(19) United States
(12) Patent Application Publication
(10) Pub. No.: US 2006/0290448 A1
(43) Pub. Date: Dec. 28, 2006

(54) Tunable resonant cable trap

(76) Inventors: Tracy Allyn Wynn, McIntosh, FL (US); David A. Molyneaux, Gainesville, FL (US)

Correspondence Address: QUARLES & BRADY LLP, 411 E. WISCONSIN AVENUE, SUITE 2040, MILWAUKEE, WI, 53202-4497, US

(21) Appl. No.: 11/166,890

(22) Filed: Jun. 24, 2005

(51) Int. Cl. H03H 7/01

(52) U.S. Cl. 333/176

(57) ABSTRACT

A resonant cable trap for use with a shielded cable having an outer shield surrounding at least one inner conductor includes first and second members and a coil defined in the outer shield. The first member has a first conductive surface coupled to the shield. The second member has a second conductive surface coupled to the shield and is disposed to overlap at least a portion of the first member. The first and second conductive surfaces define a capacitor. The capacitor is coupled to the shield in parallel with the coil. A method for tuning the resonant cable trap includes adjusting the amount of overlap between the first and second members to tune the resonant frequency of the resonant cable trap.

### CROSS-REFERENCE TO RELATED APPLICATIONS

Not applicable.

### STATEMENT REGARDING FEDERALLY SPONSORED RESEARCH OR DEVELOPMENT

Not applicable

### BACKGROUND OF THE INVENTION

The present invention relates generally to radio frequency traps and, more particularly, to a tunable resonant cable trap suitable for use with magnetic resonance imaging equipment.

This section of this document is intended to introduce various aspects of art that may be related to various aspects of the present invention described and/or claimed below. This section provides background information to facilitate a better understanding of the various aspects of the present invention. It should be understood that the statements in this section of this document are to be read in this light, and not as admissions of prior art.

Electrical conductors used for transmitting signals susceptible to external electromagnetic noise often employ a center conductor surrounded by a conductive shield. The shield is typically grounded to prevent external electric fields from influencing the signal on the central conductor. A common “coaxial cable” shielded conductor, used for radio-frequency (RF) signals, employs a braided or solid shield surrounding a central multi-strand or solid conductor separated from the shield by an insulator of predetermined diameter and dielectric properties. The shield is surrounded, in turn, by a second insulator that protects the shield from damage or electrical contact with other conductors.

In applications where there are intense external electrical/magnetic fields, for example, in magnetic resonance imaging (MRI), significant current may be induced in the shield, causing failure of the shielding effect and possibly damage to the shield and its adjacent insulation from heating. One method of reducing shield current employs an S-trap in which the coaxial cable is wound in a first direction and then optionally a second direction about a cylindrical form to produce a self-inductance among the coils of each winding set. A capacitance is connected in parallel with the inductance (by attaching leads of a capacitor to the shield at separated points in each winding) providing parallel resonant circuits tuned to the particular frequency of the offending external radio frequency field. The resonance provides the shield with a high impedance at the frequency of the interference, resisting current flow at this frequency, while the counter-winding reduces inductive coupling of the trap to the noise.

Another technique for constructing a cable trap involves winding the cable shield to increase its inductance and connecting a capacitor in parallel to the winding to resonate with this inductance. Commonly, the windings are encased in a conducting cylinder that is broken around its circumference to allow the capacitors to be attached. These breaks, however, reduce the shielding effectiveness of the enclosure, and the exposed capacitors provide a potential site for coupling.

Yet another technique, referred to as a floating shield current trap, inductively couples the shield to an inductive member and associated capacitors. No ohmic connection exists between the shield and the trap. In such traps, it is sometimes difficult to achieve enough impedance through the magnetic coupling to provide an effective trap. The effectiveness of this floating shield current trap requires that it be closely tuned to the expected frequency of the shield current.

When such traps are used with MRI equipment, the predominant shield currents will be equal to the Larmor frequency of precessing hydrogen protons within the magnetic field of the MRI machine. The Larmor frequency depends on the strength of the magnet and varies among manufacturers for a given magnet size (e.g. 1.5 Tesla) and for different magnet sizes among a single manufacturer.

It would be desirable for shield current trap to tunable to the specific frequencies of a variety of systems without the open capacitors or poor magnetic coupling evident in the techniques described above.

### BRIEF SUMMARY OF THE INVENTION

The present inventors have recognized that a tunable resonant cable trap may be constructed using overlapping members with conductive surfaces coupled in a parallel with a coil defined in the shield of a coaxial cable. The resonant frequency of the cable trap may be varied by varying the degree of overlap between the members. The first and second members may be cylindrical threaded members that may be tuned by rotating one of the members with respect to the other to adjust the amount of overlap.

One aspect of the present invention is seen in a resonant cable trap for use with a shielded cable having an outer shield surrounding at least one inner conductor. The resonant cable trap includes first and second members and a coil defined in the outer shield. The first member has a first conductive surface coupled to the shield. The second member has a second conductive surface coupled to the shield and is disposed to overlap at least a portion of the first member. The first and second conductive surfaces define a capacitor. The capacitor is coupled to the shield in parallel with the coil.

Another aspect of the present invention is seen a method for tuning the resonant cable trap. The method includes adjusting the amount of overlap between the first and second members to tune the resonant frequency of the resonant cable trap.

These and other objects, advantages and aspects of the invention will become apparent from the following description. The particular objects and advantages described herein may apply to only some embodiments falling within the claims and thus do not define the scope of the invention. In the description, reference is made to the accompanying drawings which form a part hereof, and in which there is shown a preferred embodiment of the invention. Such embodiment does not necessarily represent the full scope of the invention and reference is made, therefore, to the claims herein for interpreting the scope of the invention.

### BRIEF DESCRIPTION OF THE SEVERAL VIEWS OF THE DRAWINGS

The invention will hereafter be described with reference to the accompanying drawings, wherein like reference numerals denote like elements, and:

FIG. 1 is an isometric view of a resonant cable trap in accordance with one embodiment of the present invention;

FIG. 2 is a cross section view of the resonant cable trap of FIG. 1;

FIGS. 3A, 3B, and 3C illustrate the plating present on faces of the inner cylindrical member of FIGS. 1 and 2;

FIGS. 4 and 5 are isometric and cross section views of an alternative embodiment of the resonant cable trap, respectively.

FIGS. 6 and 7 are cross section views of the resonant cable trap of FIG. 1 with an alternative inductive coil construction.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

One or more specific embodiments of the present invention will be described below. It is specifically intended that the present invention not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the present invention unless explicitly indicated as being “critical” or “essential.”

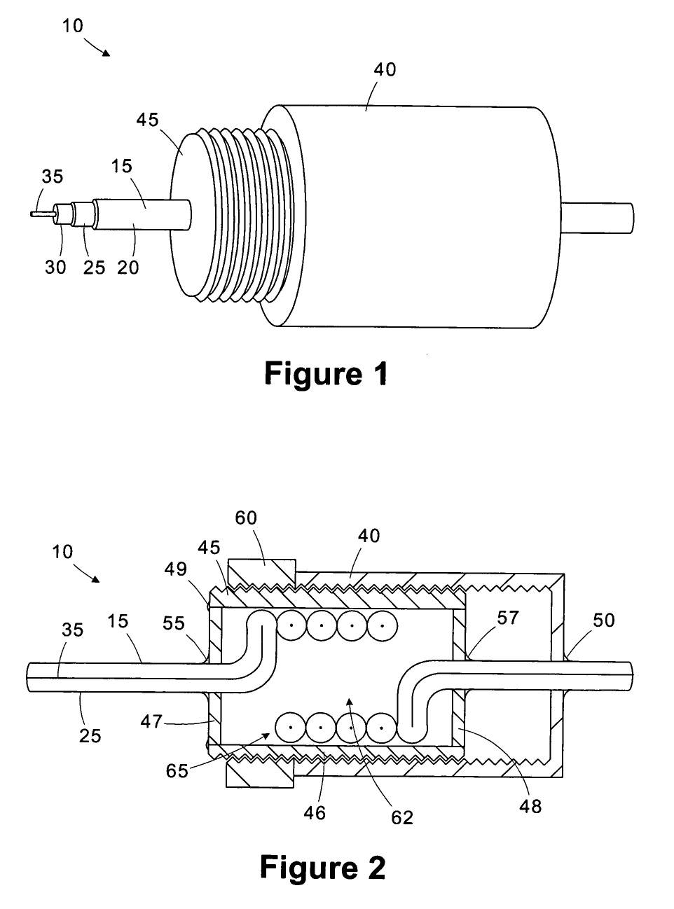

Referring now to the drawings wherein like reference numbers correspond to similar components throughout the several views and, specifically, referring to FIGS. 1 and 2, the present invention shall be described in the context of a resonant cable trap 10. The resonant cable trap 10 receives a coaxial cable 15 including an outer insulating sheath 20 fitting around a braided, rigid, or similar shield 25 covering an insulator 30 having a central signal-carrying conductor 35. For ease of illustration, only the shield 25 and conductor 35 are shown in FIG. 2. The resonant cable trap 10 includes an outer cylindrical member 40 and an inner cylindrical member 45.

Referring to FIG. 2, the outer cylindrical member 40 and inner cylindrical member 45 include conductive surfaces that overlap to define a capacitor. The outer cylindrical member 40 is electrically coupled to the shield 25 through a solder fillet 50, and the inner cylindrical member 45 is electrically coupled to the shield 25 through a solder fillet 55. As described in greater detail below, a solder fillet 57 mechanically couples the inner cylindrical member 45 to the shield 25, but does not electrically couple the portion of the inner cylindrical member 45 that defines the capacitor to the shield 25. In an embodiment where the inner cylindrical member 45 is made entirely of a conductive material, the solder fillet 57 may be omitted. Prior to forming the fillets 50, 55, 57 the insulating sheath 20 may be stripped to expose the shield 25 in locations where the connections are to be made.

The material and construction of the outer cylindrical member 40 and inner cylindrical member 45 may vary. In one embodiment, the outer cylindrical member 40 is constructed from a dielectric material (e.g., Teflon®) with a conductive plating (e.g., copper) formed on its outer surface. The inner cylindrical member 45 may be formed of an entirely conductive material (e.g., copper) or a dielectric material with a conductive plating.

The capacitance of the resonant cable trap 10 is affected by factors such as the type and thickness of the materials used for the cylindrical members 40, 45, the diameter of the cylindrical members 40, 45, and the amount of overlap between the cylindrical members 40, 45. In the embodiment of FIGS. 1 and 2, the outer cylindrical member 40 and inner cylindrical member 45 are threaded, such that the amount of overlap, and hence, the capacitance, may be varied by rotating one of the cylindrical members 40, 45 with respect to the other prior to forming one or more of the solder fillets 50, 55, 57. Alternatively, one or more of the fillets 50, 55, 57 may be removed to allow for tuning and reformed after the tuning. In yet another embodiment, their may be sufficient compliance in the coaxial cable 15 to tune the resonant cable trap 10 after the formation of one or more of the fillets 50, 55, 57.

In some embodiments, a jam nut 60 (not shown in FIG. 1) may be placed over the end of the inner cylindrical member 45 to fix the relative positions of the cylindrical members 40, 45. The jam nut 60 may be formed of a non-ferromagnetic material to avoid impacting the electrical characteristics of the resonant cable trap 10. Of course, other means may also be used to secure the relative positions of the cylindrical members 40, 45, such as a clamp or an adhesive.

Still referring to FIG. 2, the coaxial cable 15 is formed to define a coil 65. The coil 65 creates an inductance in the shield 25 in parallel with the capacitance created by the overlapping cylindrical members 40, 45. The cylindrical members 40, 45 define an annular region 62 surrounding the coil 65. The parallel capacitor and inductor form a resonant loop with a predetermined resonant frequency. A resonant loop has nearly infinite, or at least very high, impedance for signals or signal components having frequencies equal to its resonant frequency. The resonant frequency of the resonant cable trap 10 is defined by the following relationship:

$$f = \frac{1}{2 π \sqrt{LC}}$$

where L represents the inductance formed by the coil 65 in the coaxial cable 15, and C represents the capacitance of the overlapping cylindrical members 40, 45.

The value of L is determined by the geometry of the coil 65 (e.g., number of turns, turn radius, etc.). The value of C may be varied by changing the amount of overlap between the cylindrical members 40, 45. Hence, the resonant frequency of the resonant cable trap 10 may be tuned to accommodate various applications with differing signal frequencies. For example, a typical MRI machine may have expected radio frequency interference (i.e., Larmor frequency) at an approximate frequency of 64 MHz. However, the application of the resonant cable trap 10 is not limited to any particular frequency range.

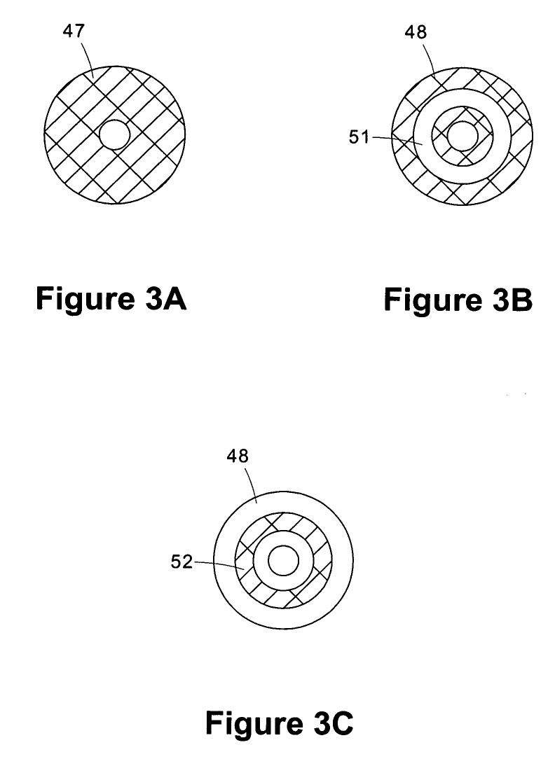

In the illustration of FIG. 2, the inner cylindrical member 45 is formed of a dielectric material with a conductive plating. The inner cylindrical member 45 includes a body member 46 and face members 47, 48. The body member 46 is plated on its interior surface. The plating of the face members 47, 48, is illustrated in FIGS. 3A, 3B, and 3C, which illustrate the plating of the outer surface of the face member 47, the outer surface of the face member 48, and the inner surface of the face member 48, respectively. The inner surface of the face member 47 is devoid of plating, and it therefore not illustrated. As seen in FIG. 3A, the outer surface of the face member 47 is plated over its entire surface. Hence, the plating on the interior surface of the body member 46 contacts the plating on the outer surface of the face member 47. An additional solder fillet 49 may be formed at the interface to enhance the electrical connection therebetween.

Referring to FIG. 3B, the outer surface of the face member 48 has a gap 51 defined in the plating on its surface. This gap 51 electrically isolates the plated portions of the body member 46 and face member 47 in the inner cylindrical member 45 that define the capacitor from the shield 25. As seen in FIG. 3C, the plating on the inner surface of the face member 47 defines a ring 52 corresponding to the gap 51 on the opposing surface.

Collectively, the plating patterns on the body member 46 and face member 47 form a noise shield. Unshielded, the coil 65 formed in the coaxial cable 15 may act as an antenna for high frequency noise, which could hinder or defeat the noise-reducing purpose of the resonant cable trap 10. The plating patterns compensate for this effect by shielding the coil 65 from all directions. The plating provided by the ring 52 which covers the gap 51 cooperates with plating on the inner surface of the face member 48 to shield the coil from noise entering the annular region 62 from a direction intersecting the face member 48. Noise could still enter the annular region 62 at an extreme angle which bypasses the ring 52 and passes through the face member 48 without hitting the plating on the inner surface, but the magnitude of such a noise component is virtually negligible.

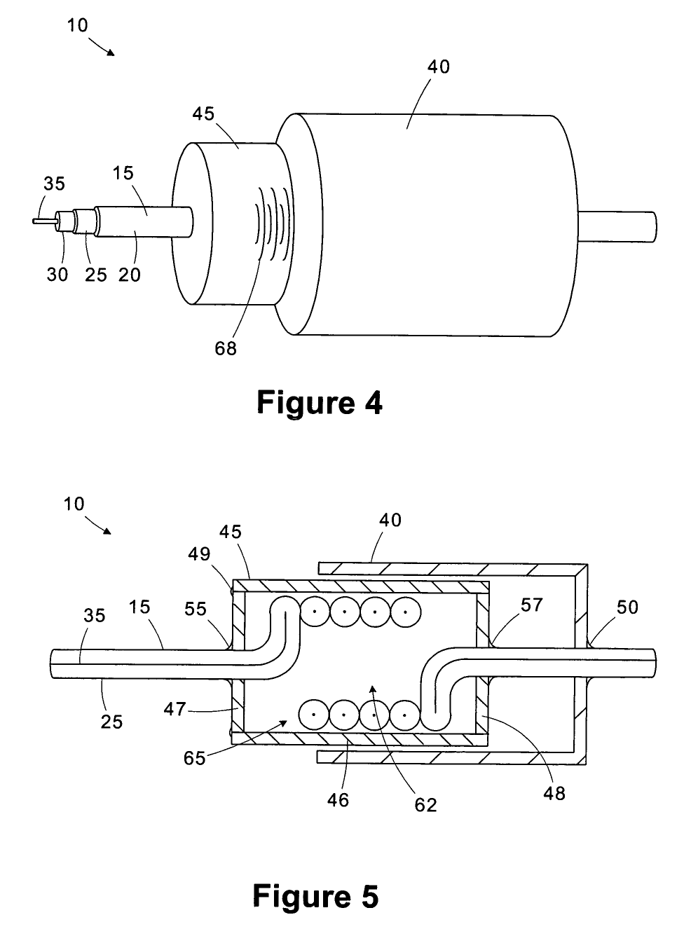

Turning now to FIGS. 4 and 5, an alternative embodiment of the resonant cable trap 10 is shown. In this particular embodiment, the outer cylindrical member 40 and inner cylindrical member 45 are not threaded, but rather, slidingly engage one another to control the amount of overlap. The dimensions of or the material used for the cylindrical members 40 and 45 may be selected to provide an interference fit therebetween. Also, a clamp or adhesive material may be used to secure the relative positions of the cylindrical members 40, 45 once the resonant cable trap 10 has been tuned.

As seen in FIG. 4, indicia 68 may be provided on the inner cylindrical member 45 to provide information regarding the amount of overlap between the cylindrical members 40, 45, and hence, tuning of the resonant cable trap 10. In the embodiment of FIGS. 1 and 2, the degree of overlap may also be indicated by the number of exposed threads on the inner cylindrical member 45 (hence, the indicia 68 may be provided by the threads rather than other markings). The overlap indicia 68 may be used to develop guidelines for tuning the resonant cable trap 10. For example, in a context where the threads provide the indicia 68, and the resonant cable trap 10 is to be used in a system with an expected interference frequency of X, it may be predetermined that m threads need to be exposed to set the proper resonant frequency. For a system with an interference frequency of Y, n threads may be exposed. Any such tuning indicia 68 assumes a common configuration for the coil 65, thereby fixing the inductance. If such consistency cannot be achieved, further tuning may be necessary, with the indicia 68 providing only a coarse indication of resonant frequency.

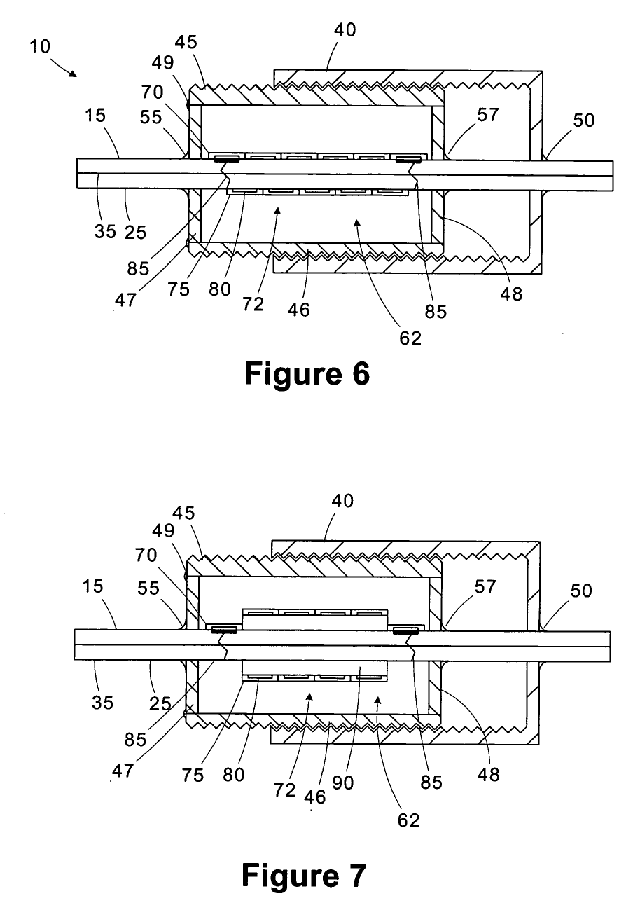

Referring now to FIGS. 6 and 7, embodiments are shown that do not employ the coil 65 in the coaxial cable 15 (shown in FIGS. 2 and 5) to provide the requisite inductance for the resonant cable trap 10. Instead, a conductor 70 is electrically coupled to the shield 25 and wrapped around the coaxial cable 15 to define an inductive coil 72 in parallel with capacitor formed by the cylindrical members 40, 45. In one embodiment, the conductor 70 may be a conductive tape including an insulating material 75 covering on one side or encapsulating a conductive material 80 (e.g., conductive wire or foil). The conductor 70 may be wrapped around the coaxial cable 15 in a non-overlapping fashion shown in FIG. 6, or alternatively, in an overlapping fashion. Breaks 85 in the shield 25 may be formed to interrupt the continuity of the shield 25 in the region where the conductor 70 is wound to avoid short circuiting the inductive coil 72.

In the embodiment of FIG. 7, the conductor 70 is wrapped around a form 90 to increase the radius of the turns in the coil 72, thereby increasing its inductance. The form 90 may be ferromagnetic to further increase the inductance of the coil 72.

The resonant cable trap 10 is not limited to the cylindrically shaped overlapping members 40, 45 illustrated. The circular cross section is useful in the embodiment of FIGS. 1 and 2 where the member 40, 45 are engaged by threads. However, in the embodiment of FIGS. 4 and 5 where threads are not employed, other cross sections, such as rectangular, oval, etc. may be used.

The various embodiments described herein provide a resonant cable trap 10 that may be readily tuned to adjust its resonant frequency to match the frequency of expected or measured interference of its intended application. Hence, a particular configuration of the resonant cable trap 10 may be used in a variety of applications (e.g., varying manufacturers or magnet sizes).

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

We claim:

1. A resonant cable trap for use with a shielded cable having an outer shield surrounding at least one inner conductor, comprising:
a first member having a first conductive surface coupled to the shield;
a second member having a second conductive surface coupled to the shield and being disposed to overlap at least a portion of the first member, the first and second conductive surfaces defining a capacitor; and
a coil defined in the outer shield, wherein the capacitor is coupled to the shield in parallel with the coil.

2. The resonant cable trap of claim 1, wherein the first and second members comprise cylinders.

3. The resonant cable trap of claim 1, wherein the coil is defined by a number of turns of the shielded cable.

4. The resonant cable trap of claim 1, wherein the coil comprises a conductor coupled to the shield and coiled around the shielded cable.

5. The resonant cable trap of claim 4, further comprising a form surrounding at least a portion of the shielded cable, wherein the conductor is coiled around the form.

6. The resonant cable trap of claim 4, wherein the conductor comprises insulated conductive tape.

7. The resonant cable trap of claim 2, wherein the first and second cylinders are threaded.

8. The resonant cable trap of claim 7, further comprising a jam nut engaging one of the first and second cylinders.

9. The resonant cable trap of claim 1, wherein the first member comprises a dielectric material having at least one surface plated with a conductive material to define the first conductive surface.

10. The resonant cable trap of claim 9, wherein the second member comprises a dielectric material having at least one surface plated with a conductive material to define the second conductive surface.

11. The resonant cable trap of claim 9, wherein the second member comprises a conductive material.

12. The resonant cable trap of claim 1, wherein the first and second members define an annular region, the coil being disposed within the annular region.

13. The resonant cable trap of claim 1, further comprising indicia defined on the first member indicating an amount of overlap between the first and second members.

14. The resonant cable trap of claim 13, wherein the first and second members are threaded, and the indicia comprises a number of threads exposed on the first member.

15. A method for tuning a resonant cable trap for use with a shielded cable having an outer shield surrounding at least one inner conductor, comprising:
defining a coil in the outer shield;
coupling a first member having a first conductive surface to the shield;
coupling a second member having a second conductive surface to the shield, the second member overlapping at least a portion of the first member, the first and second conductive surfaces defining a capacitor coupled to the shield in parallel with the coil; and
adjusting the amount of overlap between the first and second members to tune the resonant frequency of the resonant cable trap.

16. The method of claim 15, wherein the first and second members comprise cylinders.

17. The method of claim 15, wherein defining the coil further comprises forming a number of turns in the shielded cable.

18. The method of claim 15, wherein defining the coil further comprises:
winding a conductor around the shielded cable; and
coupling the conductor to the shield.

19. The method of claim 18, further comprising:
providing a form surrounding at least a portion of the shielded cable; and
winding the conductor around the form.

20. The method of claim 19, wherein the conductor comprises insulated conductive tape.

21. The method of claim 16, wherein the first and second cylinders are threaded, and adjusting the amount of overlap further comprises rotating one of the first and second members about the other of the first and second members.

22. The method of claim 21, further comprising engaging a jam nut with one of the first and second cylinders.

23. The method of claim 15, wherein the first member comprises a dielectric material having at least one surface plated with a conductive material to define the first conductive surface.

24. The method of claim 23, wherein the second member comprises a dielectric material having at least one surface plated with a conductive material to define the second conductive surface.

25. The method of claim 23, wherein the second member comprises a conductive material.

26. The method of claim 15, wherein the first and second members define an annular region, the coil being disposed within the annular region.

27. The method of claim 15, further comprising defining indicia on the first member indicating an amount of overlap between the first and second members.
